(19) United States
(12) Patent Application Publication
(10) Pub. No.: US 2026/0088190 A1
(43) Pub. Date: Mar. 26, 2026

(54) PULSED POWER SYSTEM WITH ENHANCED PULSE SHAPING

(71) Applicant: XCIMER ENERGY, INC., Denver, CO (US)

(72) Inventor: Doug Weidenheimer, Denver, CO (US)

(21) Appl. No.: 19/333,248

(22) Filed: Sep. 18, 2025

Related U.S. Application Data
(60) Provisional application No. 63/697,344, filed on Sep. 20, 2024.

(51) Int. Cl. G21B 1/21; G21B 1/03; G21B 1/23; H03K 5/12

(52) U.S. Cl. CPC G21B 1/21; G21B 1/03; G21B 1/23; H03K 5/12

(57) ABSTRACT

A pulsed power generator includes a first plurality of capacitive stages coupled together. Each capacitive stage of the first plurality of capacitive stages includes a plurality of capacitors, one or more switches for erecting the plurality of capacitors, and a conductive band forming a loop around the plurality of capacitors. The conductive band is to carry a current between the plurality of capacitors and to couple adjacent capacitive stages of the first plurality of capacitive stages. The pulsed power generator includes a pulse shaping circuit at an output of the first plurality of capacitive stages.

### CROSS REFERENCE TO RELATED APPLICATIONS

This application claims the benefit of and priority to U.S. Provisional Application Ser. No. 63/697,344, entitled “PULSED POWER SYSTEM WITH ENHANCED PULSE SHAPING” and filed on Sep. 20, 2024, which is expressly incorporated by reference herein in its entirety.

### TECHNICAL FIELD

This disclosure is in the field of power generators, and in particular, to a pulsed power system.

### BACKGROUND

Pulsed power systems, such as a Marx generator or Marx Pulse Forming Network (PFN), generate high voltage pulses by charging several capacitors in parallel and then suddenly switching, or “erecting”, the capacitors into a series, thus generating a large but relatively short voltage pulse as the capacitors discharge.

Pulsed power systems can be used to power generate a high voltage, high current, electron beam. Such an electron beam can be used to power an excimer laser. For example, the electron beam can be used to place a gas into a high energy state which decays to a lower energy state to generate a high energy laser beam.

Additionally, an excimer laser may be used for inertial confinement fusion (ICF) systems. ICF systems may be used for research purposes in high-energy physics, and are being investigated for use in energy production.

### BRIEF DESCRIPTION OF THE DRAWINGS

FIG. 1A is an example of a perspective view of a pulsed power system, according to some embodiments.

FIG. 1B is an example of a side view of a pulsed power system, according to some embodiments.

FIG. 2A depicts an example of an internal structure of a capacitive stage, according to embodiments described herein.

FIG. 2B depicts an example of a current carrying conductive band for electrically coupling of capacitive stages, according to embodiments described herein.

FIG. 2C depicts an example of a capacitive stage, according to embodiments described herein.

FIG. 3 depicts an example of a cross-section view of a pulsed power system illustrating a magnetic field generated by a current during pulse generation, according to some embodiments.

FIG. 4A depicts an example of a pulse shaping circuit, according to some embodiments.

FIG. 4B depicts an example of a saturating magnetic switch, according to some embodiments.

FIG. 4C depicts an example of a perspective view of a pulse shaping circuit, according to some embodiments.

FIG. 4D depicts an example of another perspective view of a pulse shaping circuit, according to some embodiments.

FIGS. 5A-5E illustrate examples of a peak shape and peak rise time comparison between embodiments described herein and conventional systems, according to some embodiments.

FIG. 6 is an example of a block diagram illustrating a pulsed power system, according to some embodiments.

### DETAILED DESCRIPTION

Systems for inertially confined fusion include directing a laser at a small pellet of fuel to heat the fuel at a rate fast enough to cause fusion between atoms of the fuel before they accelerate away from one another. To provide a laser with sufficiently high energy to initiate inertial fusion, a high current, high voltage electron beam is generated and directed into a gas. The electrons deposit energy in the gas allowing light amplification by stimulated emission of radiation to occur. A laser chamber may include various mirrors to redirect light through the excited gas to create the laser beam. To generate such a high current high voltage electron beam, a pulsed power generator system such as a Marx generator or Marx-PFN may be used to power an electron generating diode or cathode.

Conventional pulsed power systems, however, provide limited control of the shape of the pulse and may also require a very large area to obtain a pulse shape of sufficient quality. For example, the rise time of a pulse (e.g., the time take to go from ground state to the high voltage state) may be a factor for wear within such a high voltage system. The rise time is a period of stress within the system that does not provide any additional value to the system, for example, because a minimum voltage may be necessary to drive the laser. Accordingly, the rise time should be minimal. Additionally, conventional pulsed power systems provide a trade-off between size and pulse duration. For example, conventional pulse shaping methods such as a distributed pulse shaping water line may require longer lines for longer pulses. In some cases, to shape of pulse on the scale of microseconds, the described shaping line may be hundreds of meters long. Accordingly, for applications that require pulses of microseconds or more, such as inertially confined fusion, conventional approaches are not practical.

Embodiments described herein address the deficiencies discussed above by providing a current carrying band around the perimeter of each stage in a high voltage producing Marx/Marx-PFN column(s) or chain(s). The current carrying band at each stage may limit the volume in which a magnetic field between the generator and the container of the generator is created. Accordingly, as the area (on-axis) occupied by the magnetic field is reduced in comparison to conventional Marx/Marx-PFN systems, the amount of inductance incurred is also reduced (as inductance is directly proportional to the magnetically fluxed area) in the axial view. The reduced inductance within the container allows the circuit to be erected and discharged faster thus reducing the rise time of the voltage pulse output and pulse-shape from the Marx column/chain.

Additionally, to further sharpen the rise time of the output pulse, embodiments provide a pulse shaping circuit between the output of the Marx/Marx-PFN column/chain and the electron generating cathode or other load powered by the pulsed power system. In particular, the pulse shaping circuit may include an array of water capacitors, which re-store a portion of the energy generated by the Marx column/chain, followed by one or more saturating magnetic switches, each of which saturates after a short period of time depending on the volt-second product of the magnetic cores (e.g., on the scale of 100 nanoseconds). Accordingly, the energy at the front end of the pulse generated by the Marx/Marx-PFN column/chain is collected at the water capacitors and then discharged quickly via the saturating magnetic switches to produce a pulse with an even shorter rise time.

In some embodiments, the pulse shaping circuit may further include one or more relatively short, pulse shaping water lines following the saturating magnetic switches. The water lines may further refine the pulse shape prior to the output. As discussed above, in some embodiments, the output load may be an electron beam generating diode for generating an electron beam to power an excimer laser. It should be noted, however, that the embodiments described herein may be used in conjunction with any other load and be incorporated into any other application utilizing a pulsed power system.

In some aspects, a pulsed power generator is provided. The pulsed power generator includes a first plurality of capacitive stages coupled together. Each capacitive stage of the first plurality of capacitive stages includes a plurality of capacitors, one or more switches for erecting the plurality of capacitors, and a conductive band forming a loop around the plurality of capacitors. The conductive band is to carry a current between the plurality of capacitors and to couple adjacent capacitive stages of the first plurality of capacitive stages. The pulsed power generator includes a pulse shaping circuit at an output of the first plurality of capacitive stages.

In some aspects, a pulsed power system is provided. The pulsed power system includes a pulsed power generator including a first plurality of capacitive stages coupled together. Each capacitive stage of the first plurality of capacitive stages includes a plurality of capacitors, one or more switches for erecting the plurality of capacitors, and a conductive band forming a loop around the plurality of capacitors. The conductive band is to carry a current between the plurality of capacitors and to couple adjacent capacitive stages of the first plurality of capacitive stages. The pulsed power generator further includes a pulse shaping circuit at an output of the first plurality of capacitive stages. The pulsed power system includes an electron beam generating diode coupled to the pulse shaping circuit to generate an electron beam. The pulsed power system further includes a gas-filled chamber to generate a laser beam from the electron beam.

In some aspects, an inertial fusion system is provided. The inertial fusion system includes a pulsed power generator including a first plurality of capacitive stages coupled together. Each capacitive stage of the first plurality of capacitive stages includes a plurality of capacitors, one or more switches for erecting the plurality of capacitors, and a conductive band forming a loop around the plurality of capacitors. The conductive band is to carry a current between the plurality of capacitors and to couple adjacent capacitive stages of the first plurality of capacitive stages. The pulsed power generator further includes a pulse shaping circuit at an output of the first plurality of capacitive stages. The inertial fusion system includes an electron beam generating diode coupled to the pulsed power generator to generate an electron beam. The inertial fusion system includes a gas-filled chamber to generate a laser beam from the electron beam. The inertial fusion system further includes a fuel pellet to be heated by the laser beam.

In some examples, the pulse shaping circuit includes an array of water capacitors at the output of the first plurality of capacitive stages to re-store a portion of energy output from the plurality of capacitors.

In some examples, the pulse shaping circuit further includes a saturating magnetic switch located downstream of the array of water capacitors. The saturating magnetic switch is to saturate and close after a period of time to allow current from the array of water capacitors to pass through the at least one saturating magnetic switch.

In some examples, the pulse shaping circuit further includes a water line extending from the saturating magnetic switch to an output circuit comprising an electron beam generating diode.

In some examples, the pulsed power generator further includes a second plurality of capacitive stages coupled together. The second plurality of capacitive stages are located adjacent to and in parallel with the first plurality of capacitive stages.

In some examples, each of the first plurality of capacitive stages are coupled together by one or more gas filled switches.

In some examples, the conductive band of each of the first plurality of capacitive stages are electrically coupled in series with the plurality of capacitors to provide a discharge path for the first plurality of capacitive stages.

In some examples, the first plurality of capacitive stages are electrically coupled to a terminating ground plane inside an end wall of a containment tank.

In some examples, the first plurality of capacitive stages power an electron beam generating diode.

In some examples, the electron beam generating diode provides an electron beam into a gas-filled chamber to generate a laser beam.

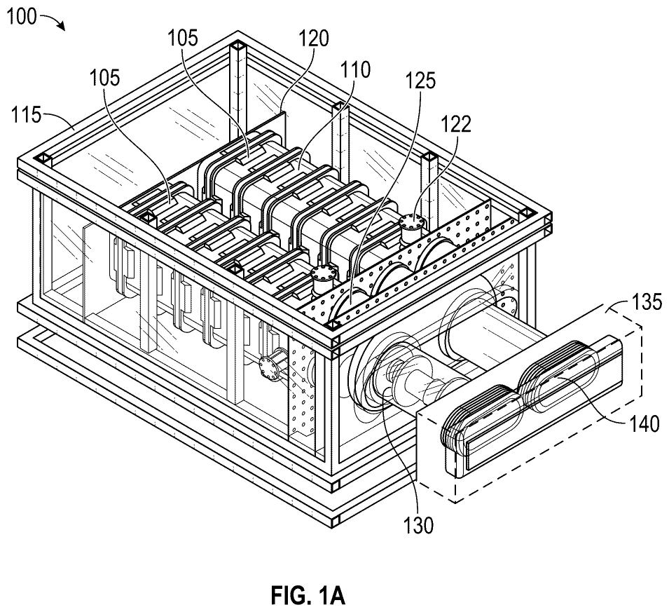

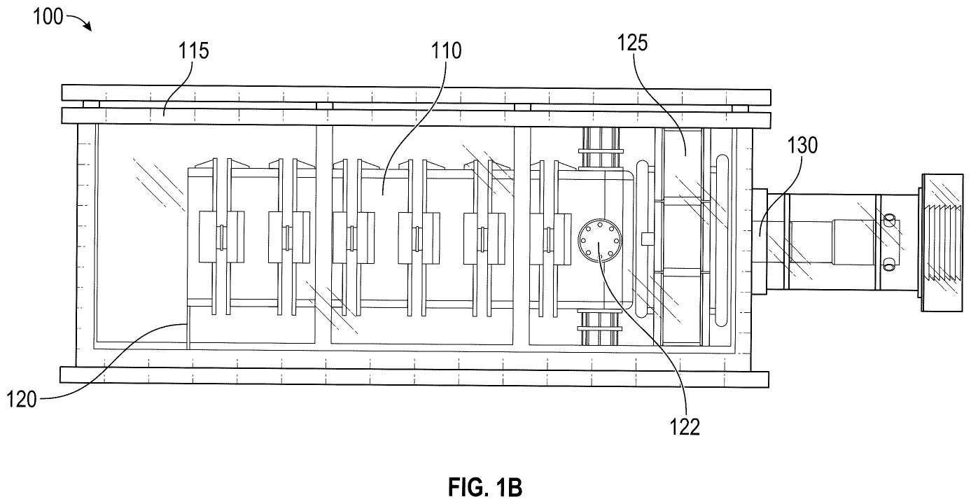

FIG. 1A depicts an example of a pulsed power system 100 according to some embodiments. The pulsed power system 100 includes a pulsed power generator, e.g., a Marx generator, a Marx-PFN. The pulsed power generator includes a first plurality of capacitive stages coupled together. Each capacitive stage of the first plurality of capacitive stages includes a plurality of capacitors, one or more switches 230 for erecting the plurality of capacitors, and a conductive band 110 forming a loop around the plurality of capacitors. The conductive band 110 is to carry a current between the plurality of capacitors and to couple adjacent capacitive stages of the first plurality of capacitive stages. The pulsed power generator further includes a pulse shaping circuit 420 at an output of the first plurality of capacitive stages. The pulsed power system 100 includes an electron beam generating diode 140 coupled to the pulse shaping circuit 420 to generate an electron beam. The pulsed power system 100 further includes a gas-filled chamber (not shown) to generate a laser beam from the electron beam generated by the electron beam generating diode 140.

In some examples, the pulsed power system 100 is included in an inertial fusion system further includes a fuel pellet. The laser beam can be targeted at the fuel pellet. More particularly, in the inertial fusion system, the laser beam is directed at the fuel pellet (or at a location where the fuel pellet is or is expected to be located) to heat fuel contained in the fuel pellet at a rate fast enough to cause fusion between atoms of the fuel before they accelerate away from one another. A laser chamber may include various mirrors to redirect light through the excited gas to create the laser beam.

The pulsed power system 100 may include a Marx generator, a Marx-PFN. The Marx-PFN is a high-voltage pulse generator that combines the voltage accumulation of a Marx generator with the waveform-shaping capabilities of a PFN. The Marx generator or the PFN-Marx includes one or more Marx columns or chains 105. As an example, the term “Marx column” refers to a series of Marx or Marx-PFN stages in a linear configuration of a column configured to multiply voltage along the column by the series of Marx or Marx-PFN stages. As an example, the term “Marx chain” refers to any configuration (or architecture) in which the stages are connected in series electrically. A “Marx chain” may be realized in numerous physical configurations (linear, single or double folded, etc.). The terms “Marx” and “Marx-PFN” are used interchangeably in this disclosure. Each Marx/Marx-PFN column or chain 105 includes multiple capacitive stages coupled together. Each capacitive stage of the multiple capacitive stages includes a plurality of capacitors, one or more switches for erecting the plurality of capacitors, and a conductive band 110 forming a loop around the plurality of capacitors. The conductive band 110 is configured to carry a current between the plurality of capacitors and to couple adjacent capacitive stages of the first plurality of capacitive stages. The Marx column or chain 105 further includes a pulse shaping circuit at an output of the multiple capacitive stages. For example, the pulse peak shaping circuit 400 is a pulse peak shaping circuit to shape a peak of an output pulse, e.g., by sharpening a rise time of the output pulse.

As depicted, the pulsed power system 100 may include one or more Marx/Marx-PFN columns or chains 105, each with multiple stages. For example, each stage of the columns may be made of energy storage capacitors and the current carrying band 110 surrounding the internal circuitry of the component. Each stage may be coupled by one or more switches, such as one or more gas switches (e.g., a plurality of gas switches), that effectively close at a preselected voltage or time. Thus, each stage may be charged separately until the circuit is triggered and each stage is erected (e.g., the switch closes). Then, all the capacitors of each stage are placed into series, resulting in a high voltage output pulse.

In some embodiments, two Marx/Marx-PFN columns 105 may be combined together into a pulsed power system 100. As depicted, the Marx columns may be deployed within a tank 115 which may be filled with an insulating liquid, such as an oil. The insulating liquid may prevent the Marx circuit from shorting to the tank. In some embodiments, the insulating liquid may be, for example, a transformer oil and may allow the Marx generator to deliver its output voltage, for example, up to 2 Megavolts, without shorting to the tank.

As can be seen in FIG. 1A, the current carrying bands 110 extend over most of the surface of the Marx/Marx-PFN stages, thus directing current along those bands/paths, which in turn minimizes the inductance of the circuit, e.g., the Marx/Marx-PFN, within the tank. Additionally, the Marx/Marx-PFN columns 105 may be coupled to a terminating ground plane 120 at a rear end of the Marx columns 105, thus further reducing the amount of inductance within the circuit within a containment tank 115 of Marx/Marx-PFN. The multiple capacitive stages, e.g., Marx/Marx-PFN stages, are electrically coupled to the terminating ground plane 120 inside an end wall of the containment tank 115. One capacitive stage of the multiple stages of the Marx/Marx-PFN columns 105 at the rear end of the Marx/Marx-PFN columns 105 may be coupled to the terminating ground plane 120. Accordingly, because the inductance within the system 100 is reduced by the example configuration, the rise time of the pulse generated by the Marx/Marx-PFN columns or chains 105 is significantly reduced. Embodiments may also include energy diverter gas switches 122 which may assist with shortening the fall time of the pulse.

To further reduce the rise time of the generator pulse, embodiments may include an array of water capacitors 125 to collect energy at an output of the Marx columns 105. For example, the array of water capacitors 125 may have a capacity of 10-20 nano-farads. The array of water capacitors 125 may have other capacities in addition to 10-20 nano-farads. When the array of water capacitors 125 receives charge, two saturating magnetic switches 130 may conduct a small amount of magnetizing current. The magnetizing current may force charge (and therefore a voltage that is held low by design) on the water transmission lines downstream of the saturating magnetic switches 130, during the magnetic switch saturation process. As an alternative or as a supplement, a resistive element can be added to the water transmission line section to further limit the voltage on the transmission line during the magnetic switch saturation process. The time to saturation may be chosen based on the intrinsic risetime of the output pulse from the Marx/Marx-PFN(s) and the risetime requirement of the load (for example, ˜100 nanosecond). Once saturated (unable to support additional magnetic flux), the saturating magnetic switches 130 will effectively close, allowing the free flow of the charge into one or more transmission lines that can also be designed for additional pulse-shaping and impedance-matching. The shaped pulse will then power an electron beam generating diode 140 to generate a high current, high voltage electron beam directed into a laser gas chamber 135.

While two Marx/Marx-PFN columns are depicted in FIG. 1A, it should be noted that any number of Marx/Marx-PFN columns may be incorporated into a pulsed power system, according to embodiments described herein. Additionally, multiple pulsed power systems may be combined in various configurations and still benefit from the embodiments described herein.

FIG. 1B is an example of a side view of the pulsed power system 100, according to some embodiments. Referring to FIG. 1B, each Marx column or chain 105 includes multiple capacitive stages, or Marx/Marx-PFN stages, coupled together. The multiple capacitive stages, or Marx/Marx-PFN stages, have multiple conductive bands 110. Each capacitive stage of the multiple capacitive stages includes multiple capacitors and a conductive band 110 of the multiple conductive bands 110. Each conductive band 110 is configured to carry a current between the multiple capacitors. In addition, each conductive band 110 is further configured to couple adjacent capacitive stages of the multiple capacitive stages, e.g., for the purpose of multiplying voltage outputs of the multiple capacitive stages. For example, each conductive band 110 may be coupled or electrically connected to one or two adjacent conductive bands of one or two adjacent capacitive stages. The conductive bands 110 are configured to provide a current path between adjacent stages in the Marx/Marx-PFN column when the Marx/Marx-PFN is erected. For example, each of the conductive bands 110 includes two equal length (on-axis) pieces, connected together with conductive fastening structures. The adjacent conductive bands of adjacent capacitive stages may also be connected together with the conductive fastening structures. The conductive bands 110 are held at ground (zero potential) with respect to the tank walls during charging of the Marx or Marx-PFN. This characteristic avoids placing a DC pre-stress on the insulating oil during charging of the Marx or Marx-PFN.

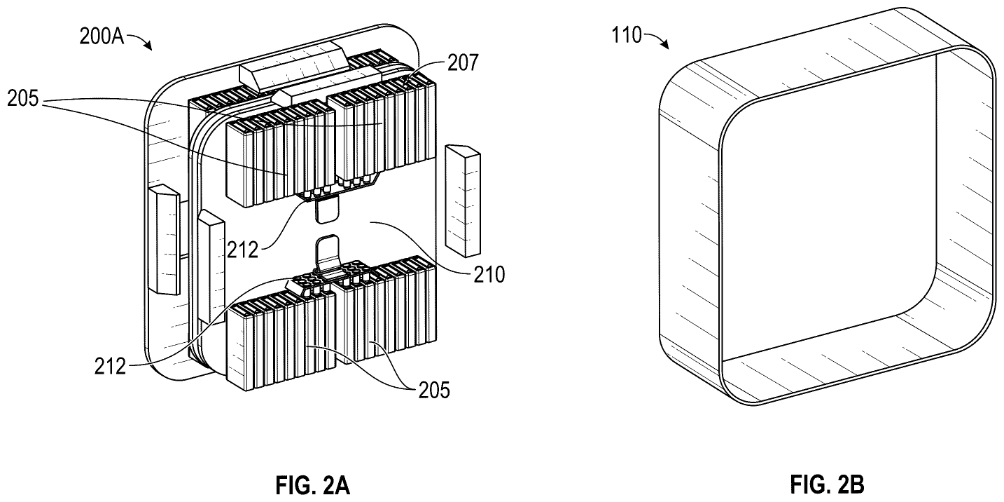

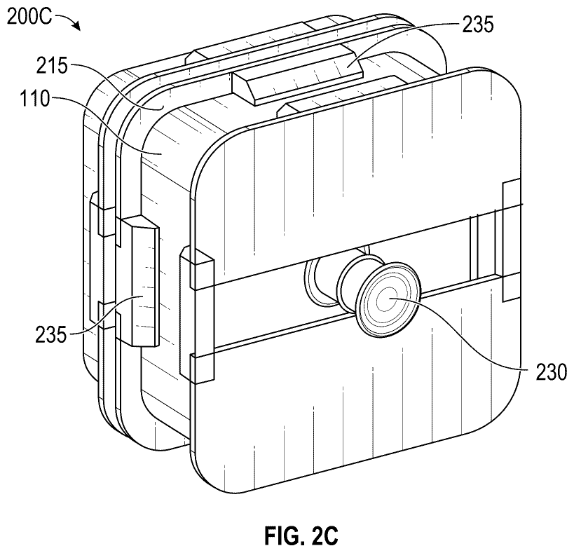

FIG. 2A depicts an example of an internal structure of a capacitive stage, e.g., Marx/Marx-PFN stage 200A according to embodiments described herein. For example, the Marx stage 200A may be incorporated into a Marx column or chain as described with respect to FIG. 1A. In some embodiments, the stage 200A includes multiple energy storage capacitors 205, e.g., energy storage capacitors in the Marx-PFN configuration, and a solid dielectric barrier 210. The energy storage capacitors 205 may be rated up to as much as 100 kilovolts and are charged from a direct current (DC) supply. The dielectric barrier 210 separates the stages of coupled stages in a Marx chain, and thus prevents shorting of the successive bands to one another when the Marx/Marx-PFN erects. In some embodiments, the energy storage capacitors 205 may include a conducting terminal/contact 207 that provides for electrical contact with the current carrying band 110, also depicted in FIG. 2B. Accordingly, when the circuit is erected, the current may travel through the current carrying band 110 from one half stage of the Marx column or chain to the next half stage.

FIG. 2B depicts an example of the current carrying conductive band 110 for electrically coupling of Marx stages, according to embodiments described herein. Referring to FIG. 2B, the conducting band 110 may be configured to be placed around a perimeter or external portion of the Marx stage 200A such that it is contact with the conducting contacts 207 of the energy storage capacitors 205. Furthermore, each of the energy storage capacitors 205 may be coupled to an electrical bus 212, each of which extends to the center of the dielectric barrier 210 of the stage 200A to be coupled with a switch 230, as depicted in FIG. 2C. In some embodiments, each half stage of the stage 200A includes four Marx PFNs in parallel.

FIG. 2C depicts an assembled stage 200C, according to embodiments described herein. Referring to FIG. 2C, which depicts as assembled stage 200C, e.g., Marx/Marx-PFN stage, (the stage 200C and half of another stage is shown in FIG. 2C), the stage switch 230 may be a gas filled switch configured to break down (close) at a predetermined voltage or time, allowing voltage to be accumulated along the Marx column or chain depicted in FIG. 1A. The gas filled switch 230 for example may be coupled to the electrical bus 212 (e.g., via direct contact with the bus or leads of the bus). Accordingly, each of the stages may be coupled in succession by the gas filled switches 230 and the current carrying bands 110. The assembled stage 200C may further include stage mounting features 235 for coupling of the current carrying band 110 and the separate stages together into a Marx column/chain.

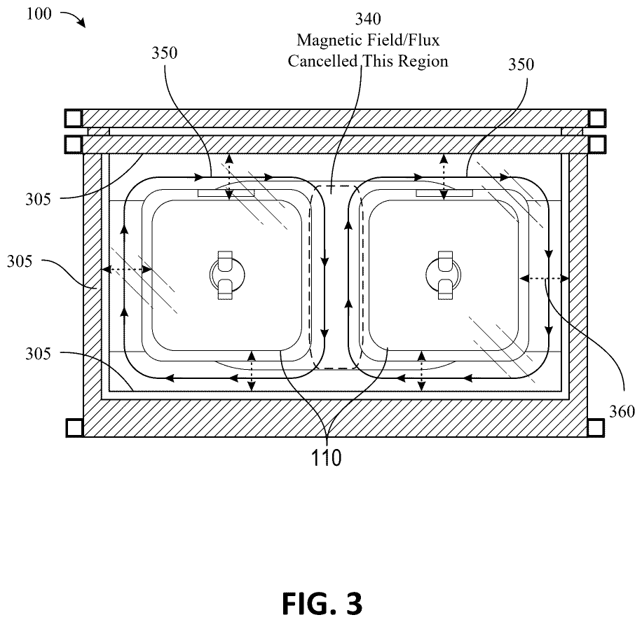

FIG. 3 is a cross-section (on-axis) view of the pulsed power system 100 depicted in FIGS. 1A-B, showing the magnetic field/flux 350 generated by a current in each Marx column during pulse generation. As provided by the view of FIG. 3, the electric current flows through the conductive current carrying bands 110 and the gas filled switches 230. Accordingly, the magnetic flux 350 generated by the two Marx columns or chains encircle the Marx columns or chains in a clockwise direction. As such, the magnetic flux lines are in opposing directions between the Marx columns/chains and thus largely cancel each other out in the illustrated volume 340. As can be seen in FIG. 3, the magnetic flux 350 in the illustrated volume 340 is limited to the area between the conductive current carrying bands 110 (e.g., outside of the bands) and the tank walls 305 in which the system is disposed. There is a distance 360 between the conductive current carrying bands 110 (e.g., outside of the bands) and the tank walls 305. The spacing 360 is sufficient (as determined by the accepted J. C. Martin formulae for the time-dependent breakdown of the chosen insulating oil) to achieve the function described herein. The routing of the Marx/Marx-PFN current through large-area conducting bands 110 that are conformal to the inside dimensions of the enclosure (tank) in combination with the flux cancellation between the (or any) adjacent Marx/Marx-PFN columns produces a relatively low inductance current path that preserves the pulse shape, e.g., generated by the PFN's within the stages, e.g., the Marx-PFN stages.

In some examples, the inductance in the current path in a Marx or Marx-PFN column can be greatly reduced if a significant portion of the on-axis current path is at a radius that is a significant fraction of that same current's return path (inside tank surfaces in this case). This may be accomplished through routing the current through the current carrying bands 110 that couple the capacitive stages, e.g., Marx/Marx-PFN stages. The on-axis current may not flow at a significant radius with respect to the return current path through the switches 230 that separate half-stages with the Marx or Marx-PFN column(s). For example, the percentage of the total column length where the current travels through the conducting bands may be 75 to 80% of the total length. In a more conventional Marx/Marx-PFN architecture, hoops or ribs are often used to surround the Marx/Marx-PFN internals. These hoops or ribs are held at ground potential during the charging of the Marx/Marx-PFN, thereby preventing any DC electric field between the Marx/Marx-PFN and the tank walls during charging. As an example, the presence of a DC electric field between the Marx/Marx-PFN and the return current path (tank walls) of >500 V/cm is enough to distort the classic J. C. Martin (JCM) oil pulsed breakdown formulae, and force the distance between the Marx/Marx-PFN to increase, thereby causing the parasitic inductance of the circuit to increase proportionally. The pulsed power system 100 described herein integrates the DC electric field control feature with the low inductance current carrying features to produce a geometry that has an intrinsically low inductance and the ability to preserve pulse shape as stages are added to the Marx/Marx-PFN column.

FIG. 3 illustrates that the magnetic flux is contained in the space between the inner current path and the outer return path (interior tank walls). Furthermore, when two Marx/Marx-PFN columns are placed in parallel, the magnetic flux is cancelled in the volume 340 between the two Marx/Marx-PFN columns, thus further conserving inductance, and leading to the parallel columns exhibiting inductance similar to that of a single Marx/Marx-PFN column at twice the width, and in the same tank confines.

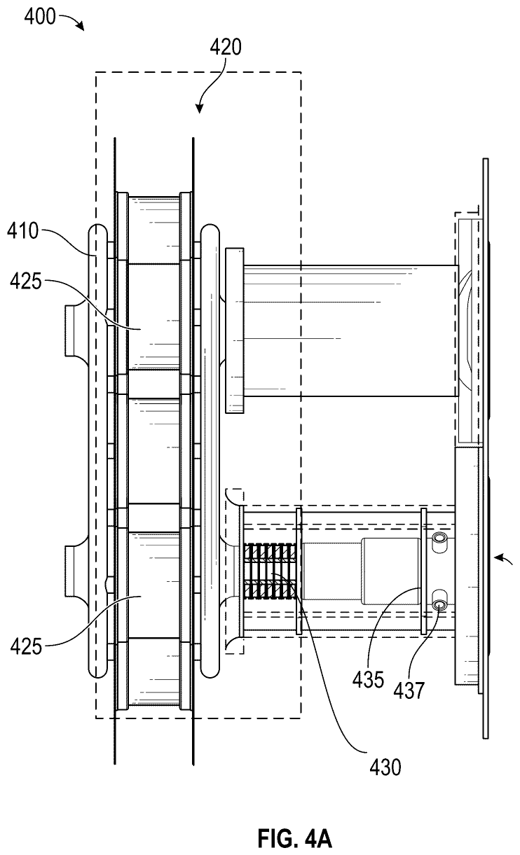

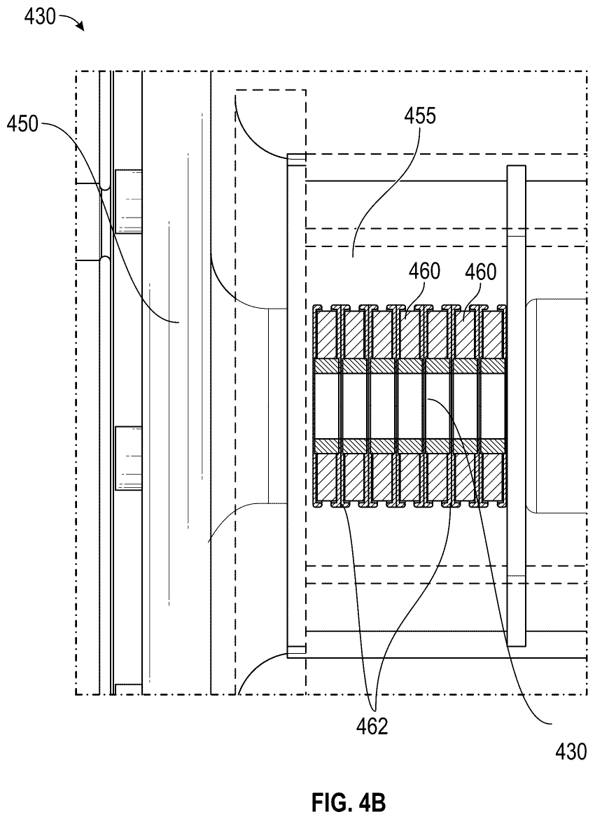

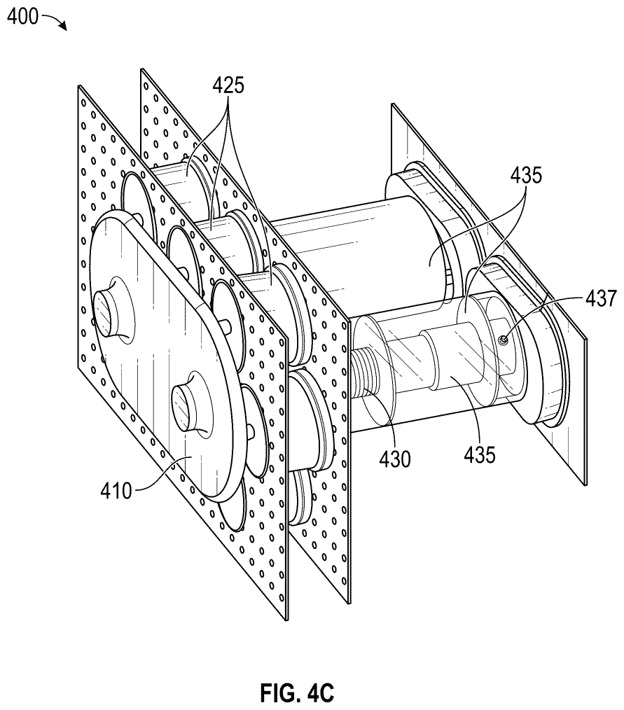

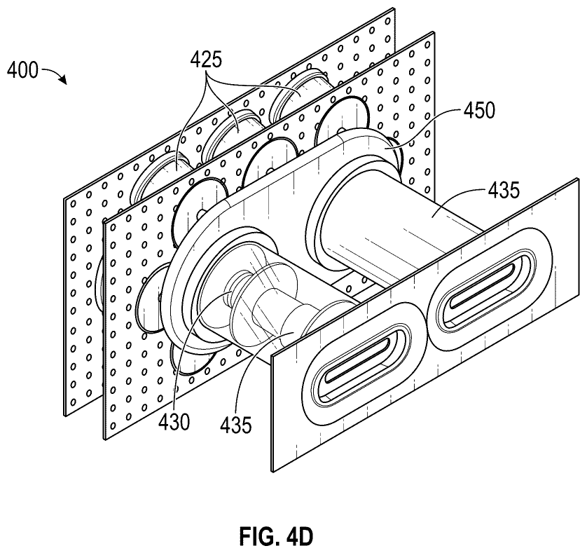

FIG. 4A depicts an example of a pulse shaping circuit 400, according to some embodiments. For example, the pulse peak shaping circuit 400 is a pulse peak shaping circuit to shape a peak of an output pulse, e.g., by sharpening a rise time of the output pulse. Referring to FIG. 4A, the pulse shaping circuit 400 may be disposed at an output of the multiple capacitive stages, e.g., Marx/Marx-PFN stages. The pulse shaping circuit 400 may include an array of water capacitors 425 at the output of the multiple capacitive stages to re-store a portion of energy output from the multiple capacitors of each capacitive stage. The pulse shaping circuit 400 may further include a saturating magnetic switch 430 located downstream of the array of water capacitors 425. The saturating magnetic switch 430 is configured to saturate and close after a period of time to allow current from the array of water capacitors 425 to pass through the saturating magnetic switch 430. The pulse shaping circuit 400 may further include one water line 435, e.g., downstream water transmission line, extending from the saturating magnetic switch to an output circuit comprising an electron beam generating diode. The features of the water line 435 will be discussed in detail below in connection with FIGS. 4C and 4D.

The pulse shaping circuit 400 may be coupled with the output of the Marx/Marx-PFN columns or chains described with respect to FIGS. 1A-B. The pulse shaping circuit 400 may include a peaking circuit 420 for shaping the output from the pulsed power system and downstream elements for further shaping. An upstream collector bus 410 may collect and distribute the output current from the Marx/Marx-PFN columns/chains and input that collected current to the array of water capacitors 425 for the purpose of charging the array of water capacitors 425 (e.g., coaxial water capacitor array). As described above, the array of water capacitors 425 may collect the charge for a period of time until the magnetic switch 430 saturates (e.g., coaxial magnetic switch) and transmits the modified-rise time pulse-shape into the water line 435, e.g., downstream water transmission line. In some embodiments, the array of water capacitors 425 may output into a single line including a single magnetic switch. Such an architecture may make use of a “racetrack geometry” magnetic switch, transmission-line and vacuum interface coupled to the entirety of the array of water capacitors 425.

In some embodiments, each water capacitor of the array of water capacitors 425 may be made as short as possible to give the desired result of collecting charge during the rise time of the Marx/Marx-PFN circuit. The on-axis length of the array of water capacitors 425 needs to be limited because of the intrinsic transit time of the pulse in water (e.g., ˜9 nanoseconds per foot). If the physical on-axis length of the array of water capacitors 425 is too long, there may be transit time effects superimposed on the leading edge and envelope of the sharpened pulse, which may be detrimental to load performance downstream of the peaking circuit 420. For example, the length of the array of water capacitor array 425 may provide sufficient charge capacity to collect the charge associated with as much as 100% of the intrinsic output risetime of the Marx/Marx-PFN columns.

FIG. 4B depicts an example of a saturating magnetic switch 430, according to some embodiments. The saturating magnetic switch 430 may include a series of toroidal magnetic cores 460 and electric field-grading features 462 disposed in a dielectric media 455, such as an insulating oil. Additionally, a water capacitor array output collector 450 may be disposed between the array of water capacitors 425 and the magnetic switch 430 to connect to the array of water capacitors 425, collect the charge from the array of water capacitors 425 and input into the at least one saturating magnetic switch (e.g., as depicted in FIG. 4A). In some embodiments, each saturating magnetic switch 430 may include electric-field grading structures 462 around the individual magnetic cores 460. These magnetic cores 460 can be co-wound from magnetic tape and an insulating layer, or wound from a coated magnetic tape, or be of an appropriate ferrite material. The saturating magnetic switch 430 may also include field grading structures 462 for the purpose of evenly distributing the electric field along the magnetic cores 460 assembly during the process of saturation when the magnetic switch is effectively “open” and the electric field is distributed along the axis of the magnetic cores 460. These structures 462 double as field control between the outer diameter of the magnetic cores 460 assembly and the outer conductor of the coaxial containment once the saturating magnetic switch has saturated (closed). In some embodiments, each saturating magnetic switch 430 may be individually tuned for flux-swing (saturation time) by a DC bias current. Thus, the saturating magnetic switches 430 may be finely tuned and synchronized with one another to ensure simultaneous saturation and switching.

In addition to the winding methods described previously, the magnetic tape of the magnetic cores 460 can be of amorphous or nanocrystalline material. Co-wound cores, as described previously, may have their turns insulated with a dielectric film or kraft paper, and then impregnated with an insulating liquid or hardening resin. Likewise, the magnetic cores 460 made from coated magnetic tape can be impregnated as well with an insulative liquid or hardening resin. In some embodiments, the magnetic cores 460 can be powder-coated for hermetic sealing, after impregnation with a hardening resin. Hermetic sealing of the magnetic cores 460 may allow their immersion in a broader range of dielectric materials, including water. The magnetic cores 460 may function as a closing switch when they reach saturation (a condition when the magnetic core 460 can hold no more magnetic flux). The time to saturation of the magnetic cores 460 depends on the total volt-see (V-see) product of the magnetic cores. The V-see product is equal to the maximum flux swing of the material times the total cross-sectional area of the material in the magnetic core. The V-see requirement for the peaking circuit is set by the peaking capacitor value and the upstream Marx-PFN circuit parameters.

FIG. 4C depicts a perspective view of an example of the pulse shaping circuit 400, according to some embodiments. Referring to FIG. 4C, each water line of the at least one water line 435 may contain one or more impedance steps for the purpose of affecting pulse-shape. Each water line may include a coaxial liquid-electrolyte resistor for the purpose of affecting pulse-shape and/or providing a path for magnetizing current (from the saturating magnetic switch) to flow. Each water line may include a diode crowbar 437 just upstream of a vacuum interface, for the purpose of quickly discharging the energy stored in the vacuum electron beam diode.

The pulse shaping circuit 400 may further include the diode crowbar 437 arrangement near the output load of the system. The diode crowbar 437 may include a water line section with multiple (e.g., nominally four) discrete gas switches connected between the outer and inner conductors of the transmission line(s). The discrete gas switches may take voltage off the load very quickly due to the proximity of the switches to the output load. In order to realize a diode crowbar switch, another possibility is to employ a multi-point triggered oil switch in the same location. Thus, the diode crowbar 437 may help reduce the fall time of the shaped output pulse at the load.

FIG. 4D depicts another perspective view of an example of the pulse shaping circuit 400, according to some embodiments. Referring to FIG. 4D, the pulse shaping circuit 400 may further include the water line 435 extending from the saturating magnetic switch 430 to an output circuit comprising an electron beam generating diode.

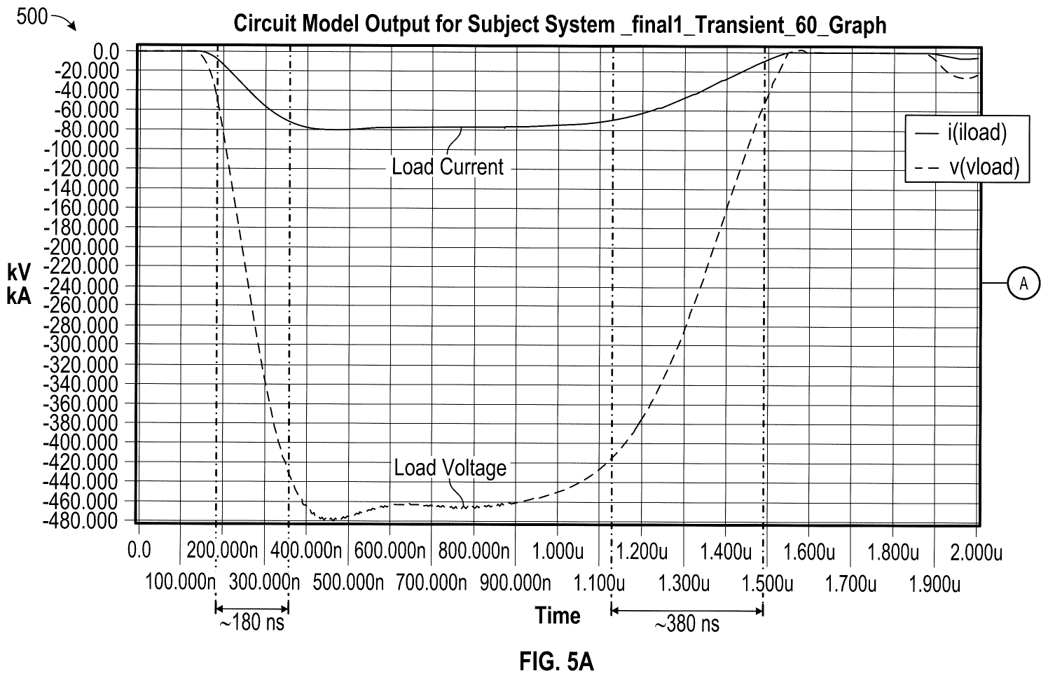

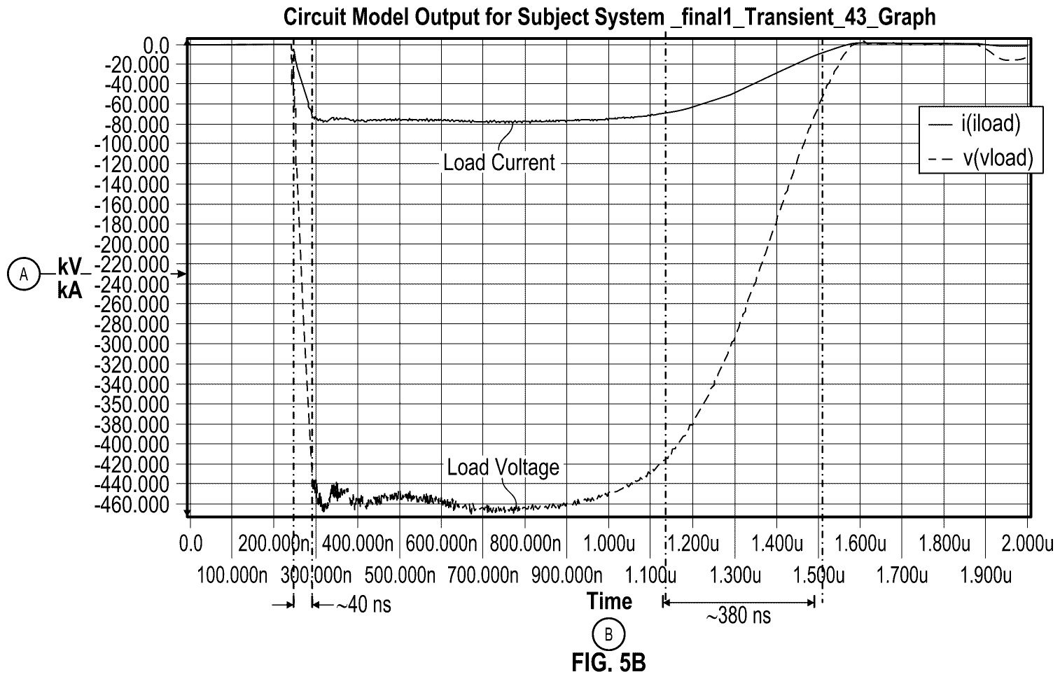

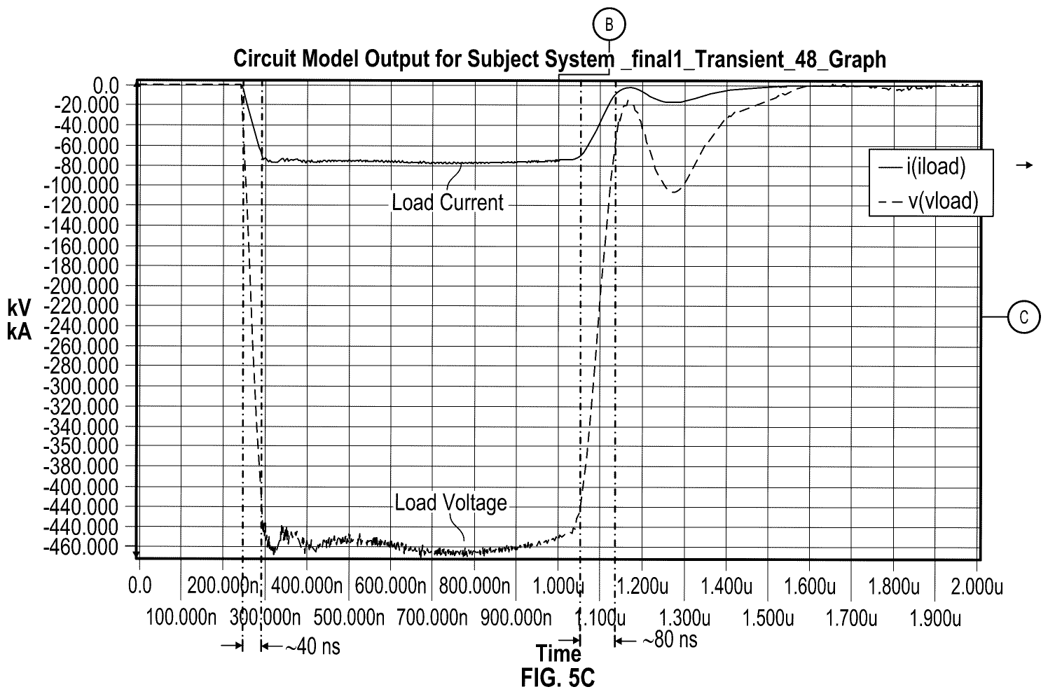

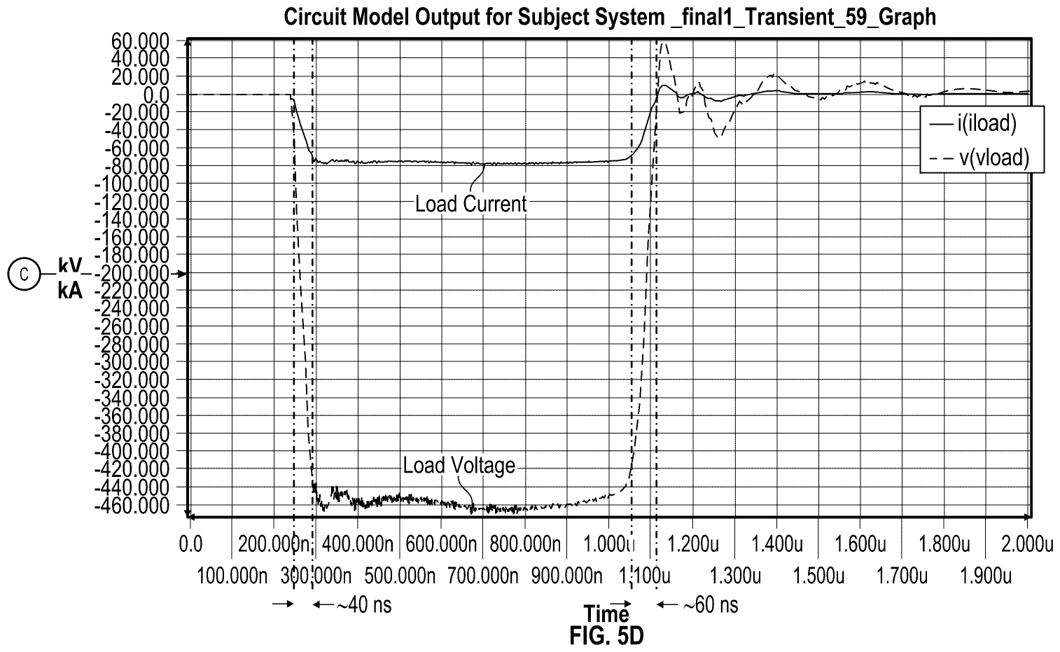

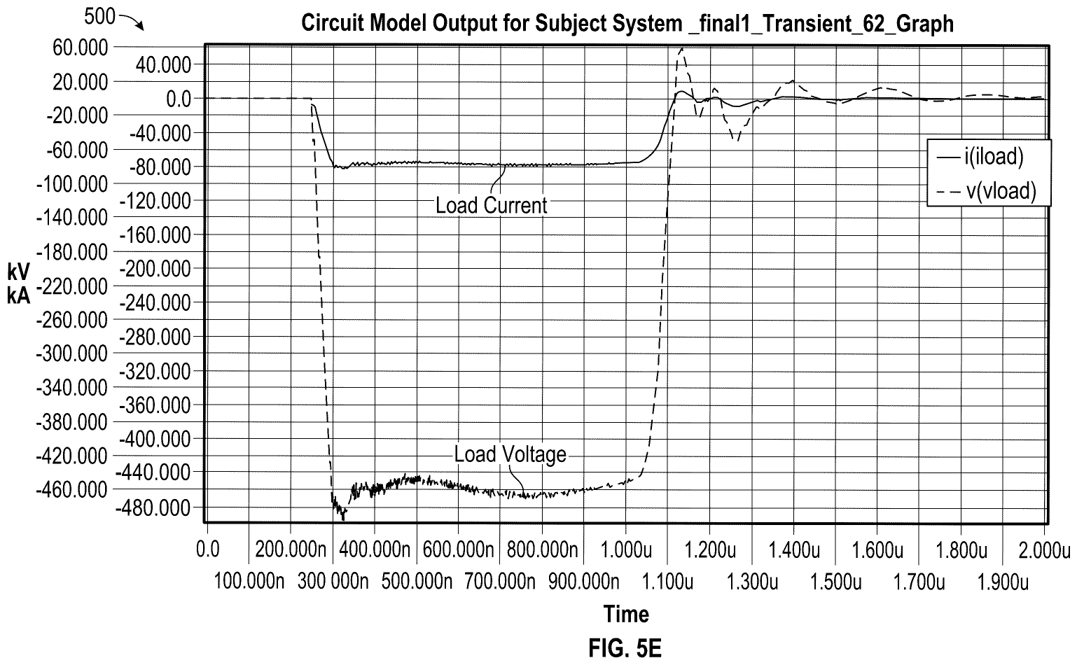

FIGS. 5A-5E illustrate examples of a peak shape and peak rise time comparison between embodiments described herein and conventional Marx-PFN, according to some embodiments. The peak amplitude of the voltage at the leading edge of the pulse can be adjusted by the value of the peaking capacitance and the time to saturation of the magnetic core(s) in the saturating magnetic switch. In some applications, such as for producing an electron beam in vacuum from a plasma or explosive emission cathode, some peaking of the voltage is desirable for fast-charging of the vacuum diode components with respect to ground.

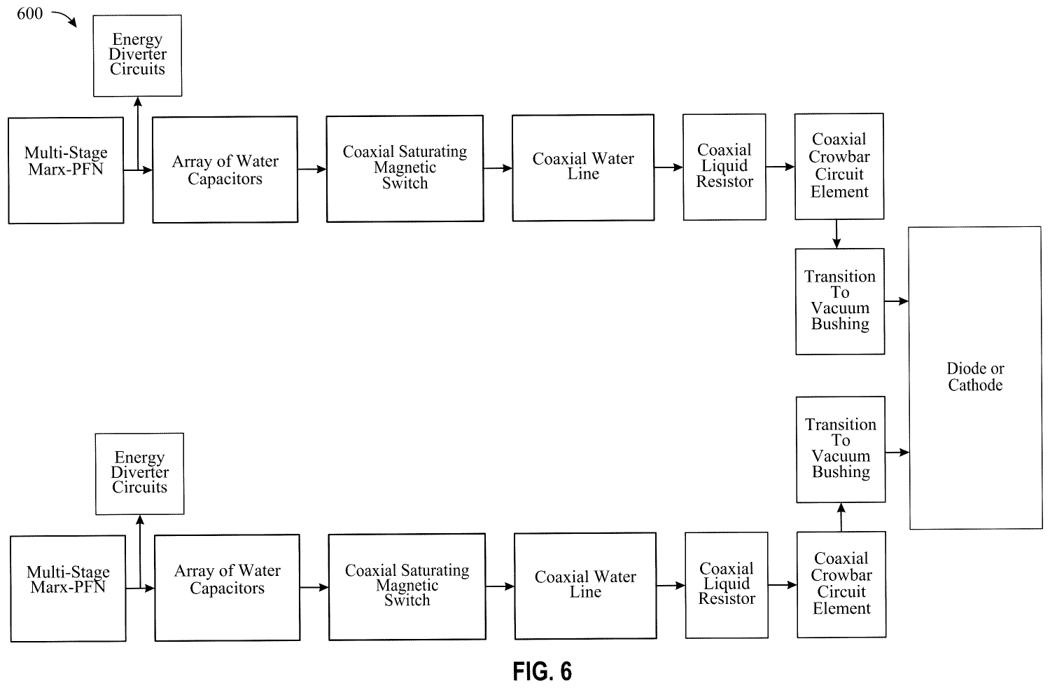

Referring to FIGS. 5A-5E, a sequence of waveforms generated at the load end of a pulsed power system (as depicted in the previous figures and in the block diagram in FIG. 6), are illustrated. FIG. 5A shows the basic pulse shape with all pulse shaping elements downstream of the Marx-PFN disabled. For example, the risetime and fall time of the delivered pulse in this case is ˜180 nanoseconds and ˜360 nanoseconds (10-90%), respectively. FIG. 5B shows the effect of the peaking circuit when enabled. For example, the rise time is reduced to ˜40 ns while the fall time remains roughly unchanged. FIG. 5C shows the effects of enabling the peaking circuit and the energy diverters at the output end of the Marx/Marx-PFN. The rise time is unchanged from the previous, but the fall time is reduced to ˜80 nanoseconds, for example. FIG. 5D shows the effect of adding a functional diode crowbar circuit just upstream of the vacuum load/diode. The rise time is unchanged, but the fall time is further reduced to ˜60 nanoseconds, as an example. FIG. 5D represents an example of a waveform for powering an electron beam that passes through a foil and into an excimer laser gas mixture. Fast rise and fall times reduce the amount of energy deposited in the foil barrier on each firing of the pulsed power system, and therefore extend the life of said foil. Finally, FIG. 5E shows the effect of a delayed peaking circuit closure causing the voltage to overshoot on the leading edge of the pulse. Such a characteristic may be helpful in some embodiments for accelerating turn-on of an explosive field emission or plasma cathode.

FIG. 6 is a block diagram illustrating an example of an entire pulsed power system 600, according to embodiments described herein. The pulsed power system 600 may be the same or similar to the pulsed power system 100 depicted in FIGS. 1A-B. As depicted in FIG. 6, the pulsed power system begins with multi-stage Marx-PFN columns, for example, two parallel 6-stage Marx-PFN columns which generate 400-520 kV into a combined 3 ohm nominal impedance load. However, it should be noted that embodiments described herein may operate with a Marx generator or Marx-PFN column/chain with any number of stages and output any voltage per stage.

At the output end of the parallel multi-stage Marx-PFN columns, an energy diverter circuit (e.g., 122) may be coupled to the output roll-up line to reduce the fall time of the trailing edge of the pulse. The output pulse is then directed into an array of water capacitors (e.g., 125, 425), for example, an array of water capacitors totaling 15 nano-Farads of capacitance. The array of water capacitors re-stores a portion of the pulse energy from the Marx/Marx-PFN column (e.g., the front end of the pulse during the rise time), during the time-to-saturation of the saturating magnetic switch.

The array of water capacitors (e.g., 125, 425) downstream may be followed by a coaxial saturating magnetic switch (e.g., 130, 430) that blocks the transmission of the pulse downstream (except for a small magnetizing current) until it saturates with flux (determined by the volt-second capacity of the cores). Once saturated, a fast-rising pulse is transmitted into the downstream transmission lines and to the load. For example, the time to saturation may be nominally 100 nanoseconds. Each downstream transmission line may be of a constant impedance along its length or may include two or more sections of different impedances for the purpose of modifying or transforming the pulse shape along its length. For example, two sections of 5 and 4 ohms may be included, each with a transit time of 7.5 nanoseconds.

A coaxial liquid resistor may be located just upstream of the diode crowbar switch array, for example. Whether to implement a coaxial resistive resistor downstream of the saturating magnetic switch (e.g., the saturating magnetic switch 430) may depend on whether the total capacitance of the downstream transmission line is sufficient to sink the magnetizing current of the saturating magnetic switch, without charging to a voltage that will produce a pre-pulse on the load that is detrimental to its performance. An example of a load that is sensitive to pre-pulse is a vacuum electron beam diode. If necessary, the coaxial resistive resistor may provide an additional current-sink for the magnetizing current of the saturating magnetic switch.

Just upstream of the vacuum interface, as an example, a diode crowbar switch may be disposed. The diode crowbar switch may be implemented in numerous ways including the following: an array of discrete gas switches arranged azimuthally between the inner and outer transmission line conductors, an array of triggered elements in a common gas or insulating oil volume, or, an array of self-breaking field-enhanced water or insulating oil sites that depend on the streamer velocity in the particular medium for closure. The function of this diode crowbar element is to discharge the energy stored in the vacuum diode so as to further reduce the fall time of the voltage on the electron beam load.

The embodiments of the system described herein may be optimized for powering an electron beam diode which passes through a thin metallic or polymer foil/window that is a vacuum/laser-gas boundary for an electron beam pumped excimer laser. Therefore, it is important that the rise and fall times of the electron beam current to be as temporally short as possible. After the coaxial liquid resistor, the coaxial crowbar circuit element, including a water line and multiple gas switches, may be used to clip a back end of the pulse. Finally, each line may transition to a racetrack vacuum bushing coupled to a load. For example, the load may be an electron beam generating diode or cathode which may be 30 cm by 200 cm and may operate at 400-520 kV and output 25 Amps per square centimeter.

It should be understood by those skilled in the art that the embodiments described herein are for exemplary purposes and should not be considered to limit the scope of the disclosure to only the specific examples or combinations listed. Embodiments of the disclosure may not contain all the characteristics listed, and not all possible combinations of characteristics or features are enumerated.

The detailed description set forth herein describes various configurations in connection with the drawings and does not represent the only configurations in which the concepts described herein may be practiced. The detailed description includes specific details for the purpose of providing a thorough explanation of various concepts. However, these concepts may be practiced without these specific details. In some instances, well known structures and components are shown in block diagram form in order to avoid obscuring such concepts.

The description herein is provided to enable a person skilled in the art to practice the various aspects described herein. Various modifications to these aspects will be readily apparent to those skilled in the art, and the generic principles defined herein may be applied to other aspects. Thus, the claims are not limited to the aspects described herein, but are to be interpreted in view of the full scope of the present disclosure consistent with the language of the claims.

Reference to an element in the singular does not mean “one and only one” unless specifically stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The terms “may”, “might”, and “can”, as used in this disclosure, often carry certain connotations. For example, “may” refers to a permissible feature that may or may not occur, “might” refers to a feature that probably occurs, and “can” refers to a capability (e.g., capable of). The phrase “For example” often carries a similar connotation to “may” and, therefore, “may” is sometimes excluded from sentences that include “for example” or other similar phrases.

Unless specifically stated otherwise, the term “some” refers to one or more. Combinations such as “at least one of A, B, or C” or “one or more of A, B, or C” include any combination of A, B, and/or C, such as A and B, A and C, B and C, or A and B and C, and may include multiples of A, multiples of B, and/or multiples of C, or may include A only, B only, or C only. Sets should be interpreted as a set of elements where the elements number one or more. Terms or articles such as “a”, “an”, and/or “the” may refer to one of an item, feature, element, etc., that the term or article precedes, or may refer to more than one of said item, feature, element, etc. that the term or article precedes. For example, the recitation “a widget” does not preclude reference to multiples of said widget, as “multiple widgets” necessarily includes “a widget”. Hence, the recitation “a widget” may be interpreted as “at least one widget” or, similarly, interpreted as “one or more widgets”.

Unless otherwise specifically indicated, ordinal terms such as “first” and “second” do not necessarily imply an order in time, sequence, numerical value, etc., but are used to distinguish between different instances of a term or phrase that follows each ordinal term.

Reference numbers, as used in the specification and figures, are sometimes cross-referenced among drawings to denote same or similar features. A feature that is exactly the same in multiple drawings may be labeled with the same reference number in the multiple drawings. A feature that is similar among the multiple drawings, but not exactly the same, may be labeled with reference numbers that have different leading numbers but have one or more of the same trailing numbers (e.g., 206, 306, 406, etc., may refer to similar features in the drawings). Hence, like numbers may refer to like actions.

Structural and functional equivalents to elements of the various aspects described throughout this disclosure that are known or later come to be known to those of ordinary skill in the art are expressly incorporated herein by reference and are encompassed by the claims. The words “module,” “mechanism,” “element,” “device,” and the like may not be a substitute for the word “means.” As such, no claim element is to be construed as a means plus function unless the element is expressly recited using the phrase “means for.” As used herein, the phrase “based on” shall not be construed as a reference to a closed set of information, one or more conditions, one or more factors, or the like. In other words, the phrase “based on A”, where “A” may be information, a condition, a factor, or the like, shall be construed as “based at least on A” unless specifically recited differently.

What is claimed is:

1. A pulsed power generator, comprising:
a first plurality of capacitive stages coupled together, wherein each capacitive stage of the first plurality of capacitive stages comprises:
a plurality of capacitors;
one or more switches for erecting the plurality of capacitors; and
a conductive band forming a loop around the plurality of capacitors, the conductive band to carry a current between the plurality of capacitors and to couple adjacent capacitive stages of the first plurality of capacitive stages; and
a pulse shaping circuit at an output of the first plurality of capacitive stages.

2. The pulsed power generator of claim 1, wherein the pulse shaping circuit comprises:
an array of water capacitors at the output of the first plurality of capacitive stages to re-store a portion of energy output from the plurality of capacitors.

3. The pulsed power generator of claim 2, wherein the pulse shaping circuit further comprises:
a saturating magnetic switch located downstream of the array of water capacitors, the saturating magnetic switch to saturate and close after a period of time to allow current from the array of water capacitors to pass through the saturating magnetic switch.

4. The pulsed power generator of claim 3, wherein the pulse shaping circuit further comprises:
a water line extending from the saturating magnetic switch to an output circuit comprising an electron beam generating diode.

5. The pulsed power generator of claim 1, further comprising:
a second plurality of capacitive stages coupled together, wherein the second plurality of capacitive stages are located adjacent to and in parallel with the first plurality of capacitive stages.

6. The pulsed power generator of claim 1, wherein each of the first plurality of capacitive stages are coupled together by one or more gas filled switches.

7. The pulsed power generator of claim 1, wherein the conductive band of each of the first plurality of capacitive stages are electrically coupled in series with the plurality of capacitors to provide a discharge path for the first plurality of capacitive stages.

8. The pulsed power generator of claim 1, wherein the first plurality of capacitive stages are electrically coupled to a terminating ground plane inside an end wall of a containment tank.

9. The pulsed power generator of claim 1, wherein the first plurality of capacitive stages power an electron beam generating diode.

10. The pulsed power generator of claim 9, wherein the electron beam generating diode provides an electron beam into a gas-filled chamber to generate a laser beam.

11. A pulsed power system, comprising:
a pulsed power generator comprising:
a first plurality of capacitive stages coupled together, wherein each capacitive stage comprises:
a plurality of capacitors;
one or more switches for erecting the plurality of capacitors; and
a conductive band forming a loop around the plurality of capacitors, the conductive band to carry a current between the plurality of capacitors and to couple adjacent capacitive stages of the first plurality of capacitive stages;
a pulse shaping circuit at an output of the first plurality of capacitive stages;
an electron beam generating diode coupled to the pulse shaping circuit to generate an electron beam; and
a gas-filled chamber to generate a laser beam from the electron beam.

12. The pulsed power system of claim 11, wherein the pulse shaping circuit comprises:
an array of water capacitors at the output of the first plurality of capacitive stages to re-store a portion of energy output from the plurality of capacitors.

13. The pulsed power system of claim 12, wherein the pulse shaping circuit further comprises:
a saturating magnetic switch located downstream of the array of water capacitors, the saturating magnetic switch to saturate and close after a period of time to allow current from the array of water capacitors to pass through the saturating magnetic switch.

14. The pulsed power system of claim 13, wherein the pulse shaping circuit further comprises:
a water line extending from the saturating magnetic switch to an output circuit comprising an electron beam generating diode.

15. The pulsed power system of claim 11, further comprising:
a second plurality of capacitive stages coupled together, wherein the second plurality of capacitive stages are located adjacent to and in parallel with the first plurality of capacitive stages.

16. The pulsed power system of claim 11, wherein each of the first plurality of capacitive stages are coupled together by one or more gas filled switches.

17. The pulsed power system of claim 11, wherein the conductive band of each of the first plurality of capacitive stages are electrically coupled in series with the plurality of capacitors to provide a discharge path for the first plurality of capacitive stages.

18. The pulsed power system of claim 11, wherein the first plurality of capacitive stages are electrically coupled to a terminating ground plane inside an end wall of a containment tank.

19. An inertial fusion system, comprising:
a pulsed power generator comprising:
a first plurality of capacitive stages coupled together, wherein each capacitive stage of the first plurality of capacitive stages comprises:
a plurality of capacitors;
one or more switches for erecting the plurality of capacitors; and
a conductive band forming a loop around the plurality of capacitors, the conductive band to carry a current between the plurality of capacitors and to couple adjacent capacitive stages of the first plurality of capacitive stages; and
a pulse shaping circuit at an output of the first plurality of capacitive stages;
an electron beam generating diode coupled to the pulsed power generator to generate an electron beam;
a gas-filled chamber to generate a laser beam from the electron beam; and
a fuel pellet to be heated by the laser beam.

20. The inertial fusion system of claim 19, wherein the pulse shaping circuit comprises:
an array of water capacitors at the output of the first plurality of capacitive stages to re-store a portion of energy output from the plurality of capacitors; and
a saturating magnetic switch located downstream of the array of water capacitors, the saturating magnetic switch to saturate and close after a period of time to allow current from the array of water capacitors to pass through the saturating magnetic switch.
